(19) United States
(12) Patent Application Publication
(10) Pub. No.: US 2025/0194096 A1
(43) Pub. Date: Jun. 12, 2025

(54) METHOD OF MANUFACTURING SEMICONDUCTOR DEVICE

(71) Applicant: Renesas Electronics Corporation, Tokyo (JP)

(72) Inventors: Yoshiki YAMAMOTO, Tokyo (JP); Atsushi AMO, Tokyo (JP); Shibun TSUDA, Tokyo (JP); Tadashi YAMAGUCHI, Tokyo (JP)

(21) Appl. No.: 18/907,980

(22) Filed: Oct. 7, 2024

(30) Foreign Application Priority Data
Dec. 6, 2023 (JP) 2023-206254

(51) Int. Cl. H10B 51/40; H10B 51/30

(52) U.S. Cl. CPC H10B 51/40; H10B 51/30

(57) ABSTRACT

A silicon film in amorphous state is formed on a semiconductor substrate located in first to fourth regions. The silicon film located in the first region and the fourth region is removed such that the silicon film located in the second region and the third region is left. A polycrystalline silicon film is formed by crystallizing the silicon film by a heat treatment.

### CROSS-REFERENCE TO RELATED APPLICATIONS

The disclosure of Japanese Patent Application No. 2023-206254 filed on Dec. 6, 2023 including the specification, drawings and abstract is incorporated herein by reference in its entirety.

### BACKGROUND

The present invention relates to a method of manufacturing a semiconductor device, and particularly relates to a method of manufacturing a semiconductor device including a ferroelectric memory cell.

In recent years, ferroelectric memory cells using ferroelectric film have been developed as semiconductor memory elements that operate at low voltages. Ferroelectric memory cells are non-volatile memory cells capable of changing the write state and erase state by controlling the direction of polarization of ferroelectric.

There are disclosed techniques listed below.
[Patent Document 1] Japanese Unexamined Patent Application Publication No. 2018-96243

Patent Document 1 discloses a semiconductor device in which a ferroelectric memory cell and a MISFET (Metal Insulator Field Effect Transistor) constituting a logic circuit are mounted together.

In a manufacturing method disclosed in Patent Document 1, first, a gate insulating film is formed on a semiconductor substrate in each of a memory cell region and a peripheral region located at a periphery of the memory cell region. Then, a ferroelectric film is formed on each of the gate insulating films. Next, a titanium nitride film is formed on the ferroelectric film. Next, the titanium nitride film and the ferroelectric film located in the peripheral region are selectively removed. Next, a polycrystalline silicon film is formed on the titanium nitride film in the memory cell region, and a polycrystalline silicon film is formed on the gate insulating film in the peripheral region. These polycrystalline silicon films are formed for use as gate electrodes of the ferroelectric memory cell and MISFET.

### SUMMARY

In the case of forming a silicon film on a titanium nitride film in a ferroelectric memory cell, conventionally, a polycrystalline silicon film is formed at a film formation temperature of about 600 degrees Celsius by a film formation process using the CVD (Chemical Vapor Deposition) method. However, the studies by the inventors of this application have revealed that abnormal growth of the polycrystalline silicon film is likely to occur on the titanium nitride film in that case. Therefore, the inventors of this application have considered forming a silicon film in amorphous state at a temperature lower than the film formation temperature of the polycrystalline silicon film, instead of the polycrystalline silicon film.

Meanwhile, in the peripheral region, a resistance element and the like are also formed as semiconductor elements other than the MISFET. The silicon film constituting the resistance element is formed by the same manufacturing step as the silicon film of the ferroelectric memory cell and the silicon film of the MISFET. Here, it has been found that if a resistance element is formed from a silicon film in amorphous state in consideration of the abnormal growth of the polycrystalline silicon film, the characteristics of the resistance element fluctuate. Specifically, it has been found that the sheet resistance of the resistance element becomes lower than the sheet resistance of the case of forming the resistance element from a polycrystalline silicon film in advance. Therefore, there is a need for a technique capable of improving the reliability of a semiconductor device by suppressing the characteristic fluctuation of a resistance element as well as suppressing abnormal growth in a ferroelectric memory cell.

For example, it is conceivable to form a silicon film in amorphous state in the memory cell region and the peripheral region, and adjust the sheet resistance by selectively implanting ions. Specifically, the decrease in the sheet resistance of the resistance element can be suppressed by performing a first ion implantation into the silicon film located in the memory cell region and performing a second ion implantation into the silicon film located in the peripheral region at a dose lower than that of the first ion implantation.

However, the number of manufacturing steps and masks required for performing the ion implantation increases, which leads to the increase in the manufacturing cost. In addition, when two types of resistance elements, p-type and n-type, are to be formed, the number of manufacturing steps and masks further increases.

If the selective ion implantation is not performed, it is also conceivable to form a silicon film in amorphous state for the ferroelectric memory cell and a polycrystalline silicon film for the resistance element separately. In this case, it is necessary to selectively leave the silicon film in amorphous state only in the memory cell region and selectively leave the polycrystalline silicon film only in the peripheral region. Accordingly, since formation and patterning of the silicon film are repeated, the number of manufacturing steps and masks increase, which leads to the increase in the manufacturing cost.

Therefore, a technique capable of improving the reliability of semiconductor devices while suppressing the increases in manufacturing cost is required. Other objects and novel features will become apparent from the description of this specification and the accompanying drawings.

An outline of a typical embodiment disclosed in this application will be simply described as follows.

A method of manufacturing a semiconductor device according to one embodiment includes a step of forming a first silicon film in amorphous state on a semiconductor substrate located in a first region and a second region, a step of removing the first silicon film located in the first region, a step of forming a first polycrystalline silicon film by crystallizing the first silicon film by a first heat treatment, a step of forming a ferroelectric film on the semiconductor substrate located in the first region and on the first polycrystalline silicon film located in the second region, a step of forming a metal film on the ferroelectric film, a step of removing the metal film and the ferroelectric film located in the second region, and a step of forming a second silicon film on the metal film located in the first region and on the first polycrystalline silicon film located in the second region.

According to one embodiment, it is possible to improve the reliability of the semiconductor device while suppressing the increase in the manufacturing cost.

### BRIEF DESCRIPTION OF THE DRAWINGS

FIG. 1 is a cross-sectional view illustrating a manufacturing process of a semiconductor device according to the first embodiment.

FIG. 2 is a cross-sectional view illustrating the manufacturing process of the semiconductor device according to the first embodiment.

FIG. 3 is a cross-sectional view illustrating the manufacturing process of the semiconductor device subsequent to FIG. 1.

FIG. 4 is a cross-sectional view illustrating the manufacturing process of the semiconductor device subsequent to FIG. 2.

FIG. 5 is a cross-sectional view illustrating the manufacturing process of the semiconductor device subsequent to FIG. 3.

FIG. 6 is a cross-sectional view illustrating the manufacturing process of the semiconductor device subsequent to FIG. 4.

FIG. 7 is a cross-sectional view illustrating the manufacturing process of the semiconductor device subsequent to FIG. 5.

FIG. 8 is a cross-sectional view illustrating the manufacturing process of the semiconductor device subsequent to FIG. 6.

FIG. 9 is a cross-sectional view illustrating the manufacturing process of the semiconductor device subsequent to FIG. 7.

FIG. 10 is a cross-sectional view illustrating the manufacturing process of the semiconductor device subsequent to FIG. 8.

FIG. 11 is a cross-sectional view illustrating the manufacturing process of the semiconductor device subsequent to FIG. 9.

FIG. 12 is a cross-sectional view illustrating the manufacturing process of the semiconductor device subsequent to FIG. 10.

FIG. 13 is a cross-sectional view illustrating the manufacturing process of the semiconductor device subsequent to FIG. 11.

FIG. 14 is a cross-sectional view illustrating the manufacturing process of the semiconductor device subsequent to FIG. 12.

FIG. 15 is a cross-sectional view illustrating the manufacturing process of the semiconductor device subsequent to FIG. 13.

FIG. 16 is a cross-sectional view illustrating the manufacturing process of the semiconductor device subsequent to FIG. 14.

FIG. 17 is a cross-sectional view illustrating the manufacturing process of the semiconductor device subsequent to FIG. 15.

FIG. 18 is a cross-sectional view illustrating the manufacturing process of the semiconductor device subsequent to FIG. 16.

FIG. 19 is a cross-sectional view illustrating the manufacturing process of the semiconductor device subsequent to FIG. 17.

FIG. 20 is a cross-sectional view illustrating the manufacturing process of the semiconductor device subsequent to FIG. 18.

FIG. 21 is a cross-sectional view illustrating the manufacturing process of the semiconductor device subsequent to FIG. 19.

FIG. 22 is a cross-sectional view illustrating the manufacturing process of the semiconductor device subsequent to FIG. 20.

FIG. 23 is a cross-sectional view illustrating the manufacturing process of the semiconductor device subsequent to FIG. 21.

FIG. 24 is a cross-sectional view illustrating the manufacturing process of the semiconductor device subsequent to FIG. 22.

FIG. 25 illustrates data acquired from experiments by the inventors of this application.

### DETAILED DESCRIPTION

Hereinafter, an embodiment will be described in detail with reference to drawings. In all the drawings for describing the embodiment, the members having the same function are denoted by the same reference characters and the repetitive descriptions thereof are omitted. Also, in the following embodiment, the description of the same or similar part is not repeated in principle unless particularly required.

### First Embodiment

### <Method of Manufacturing Semiconductor Device>

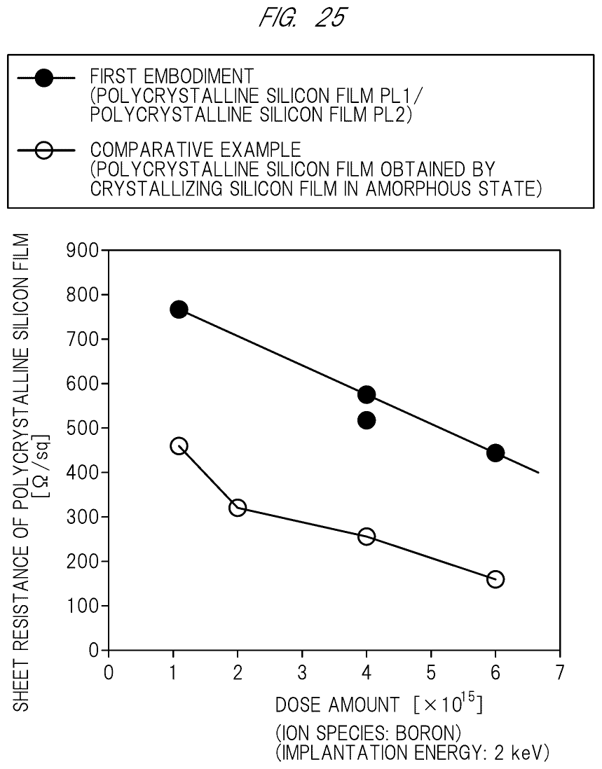

A semiconductor device includes a region 1A and regions 2A, 3A, and 4A located at a periphery of the region 1A. First, semiconductor elements formed in each region will be described with reference to FIG. 23 and FIG. 24.

As illustrated in FIG. 23, a ferroelectric memory cell MC is formed as a semiconductor element in the region 1A. The ferroelectric memory cell MC is an electrically rewritable non-volatile memory cell, and includes a memory transistor MQ and a selection transistor 1Q. The memory transistor MQ has a ferroelectric film FE, and can change the write state and erase state by controlling the direction of polarization of the ferroelectric film FE. The selection transistor 10 controls the supply of a write voltage, an erase voltage, and a read voltage to a drain region of the memory transistor MQ during the selection and non-selection of the ferroelectric memory cell MC.

In the region 2A, a plurality of MISFETs is formed as semiconductor elements. The plurality of MISFETs includes a plurality of n-type and p-type high withstand voltage MISFETs and a plurality of n-type and p-type low withstand voltage MISFETs. The plurality of high withstand voltage MISFETs constitutes, for example, a part of an I/O circuit. The low withstand voltage MISFET is driven at a voltage lower than that of the high withstand voltage MISFET and includes a gate insulating film thinner than that of the high withstand voltage MISFET. The plurality of low withstand voltage MISFETs constitutes, for example, a logic circuit including a CPU and an SRAM. In FIG. 23, an n-type high withstand voltage MISFET is illustrated as an example of the MISFET formed in the region 2A.

As illustrated in FIG. 24, a plurality of resistance elements RS1 is formed as semiconductor elements in the region 3A. A polycrystalline silicon film PL1 and a polycrystalline silicon film PL2 formed in the region 3A function as the resistance element RS1, and n-type or p-type impurities are introduced into the polycrystalline silicon film PL1 and the polycrystalline silicon film PL2. In FIG. 24, the resistance element RS1 including the n-type polycrystalline silicon and n-type film PL1 the polycrystalline silicon film PL2 is illustrated as an example of the resistance element formed in the region 3A.

In the region 4A, a plurality of resistance elements RS2 is formed as semiconductor elements. A polycrystalline silicon film PL3 formed in the region 4A functions as the resistance element RS2, and n-type or p-type impurities are introduced into the polycrystalline silicon film PL3. In FIG. 24, the resistance element RS2 including the n-type polycrystalline silicon film PL3 is illustrated as an example of the resistance element formed in the region 4A.

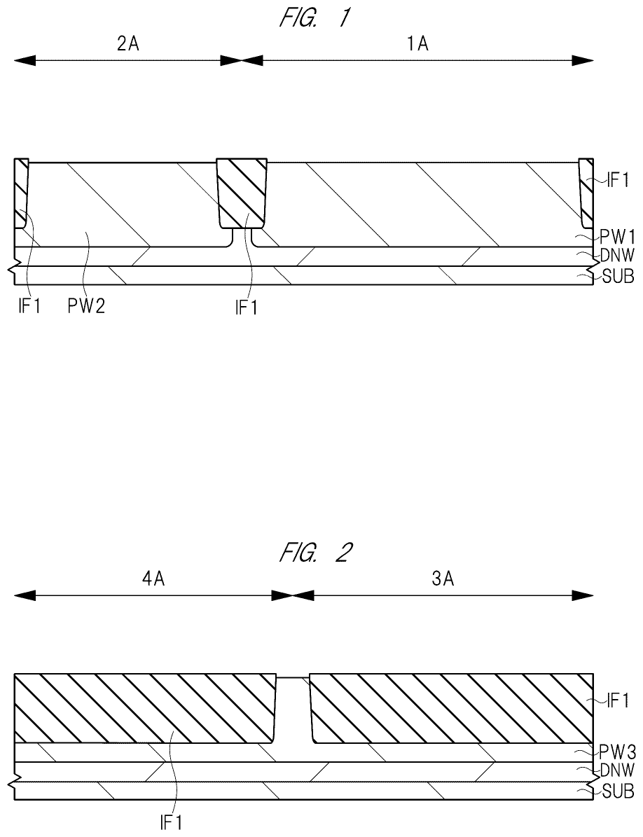

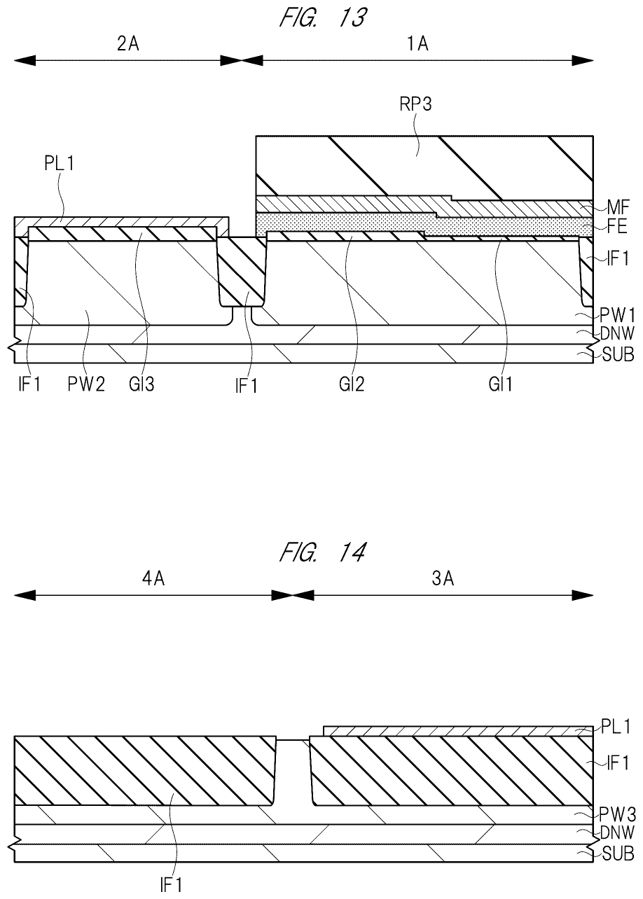

Each manufacturing step included in the method of manufacturing the semiconductor device according to the first embodiment will be described below with reference to FIG. 1 to FIG. 24.

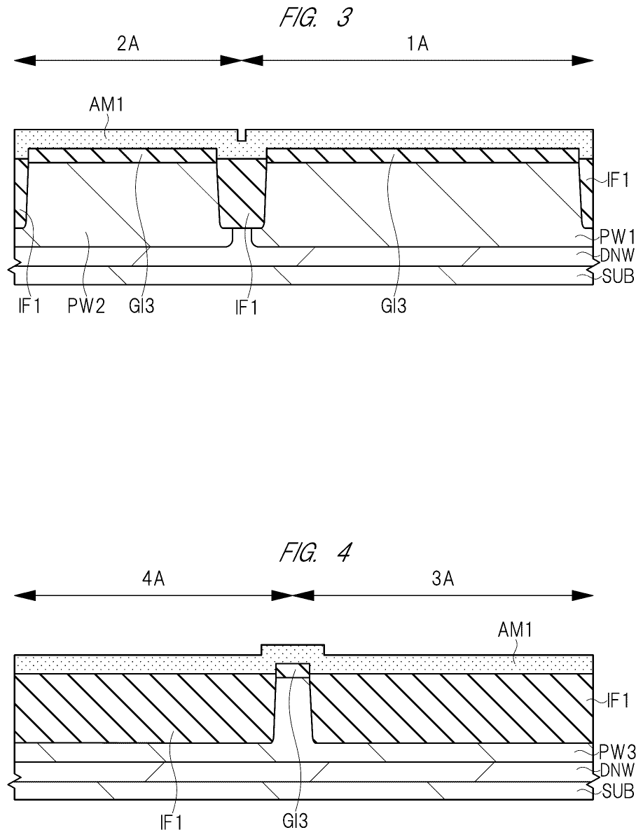

As illustrated in FIG. 1 and FIG. 2, first, a semiconductor substrate SUB made of single crystal silicon into which, for example, p-type impurities are introduced is prepared. Next, an n-type well region DNW is formed in the semiconductor substrate SUB located in the regions 1A to 4A by photolithography and ion implantation.

Next, a plurality of trenches is formed in the semiconductor substrate SUB located in the regions 1A to 4A by photolithography and anisotropic etching. Next, an insulating film IF1 is formed so as to fill the insides of the plurality of trenches by a film formation process using, for example, the CVD method. Next, the insulating film IF1 located outside the plurality of trenches is removed by a polishing process using the CMP (Chemical Mechanical Polishing) method. The insulating film IF1 functions as an element isolation portion that isolates the semiconductor elements formed in each region. A depth of the trench is, for example, 300 nm or more and 400 nm or less.

Next, by photolithography and ion implantation, a p-type well region PW1 is formed in the semiconductor substrate SUB located in the region 1A, a p-type well region PW2 is formed in the semiconductor substrate SUB located in the region 2A, and a p-type well region PW3 is formed in the semiconductor substrate SUB located in the region 3A and the region 4A.

Furthermore, although not illustrated, by photolithography and ion implantation, n-type impurities such as arsenic or phosphorus are introduced into the semiconductor substrate SUB in the region 2A where the p-type MISFET is formed, thereby forming an n-type well region.

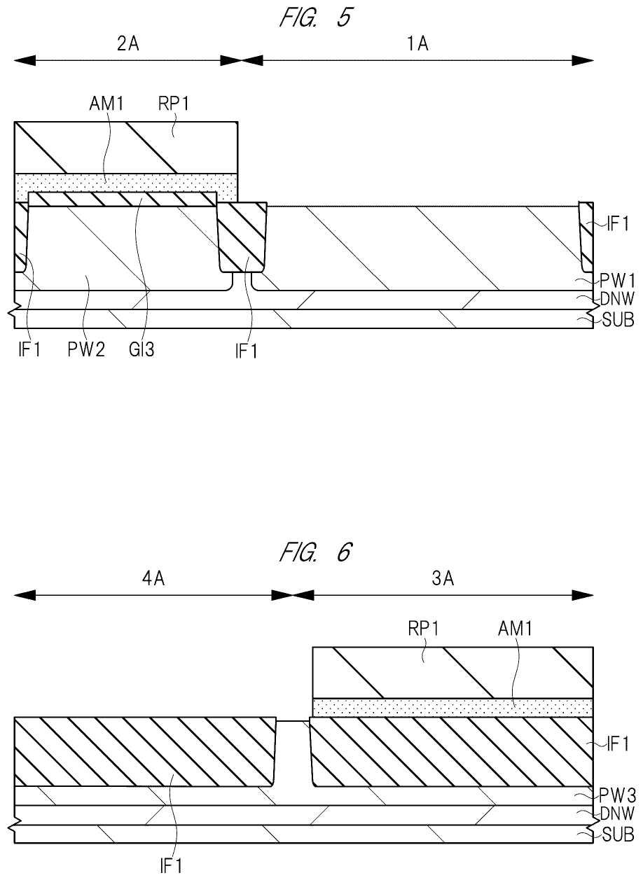

As illustrated in FIG. 3 and FIG. 4, a gate insulating film GI3 is formed on the semiconductor substrate SUB located in the regions 1A to 4A by, for example, thermal oxidation. The gate insulating film GI3 is, for example, a silicon oxide film, and has a thickness of, for example, 8 nm or more and 10 nm or less.

Next, a silicon film in amorphous state AM1 is formed on the semiconductor substrate SUB located in the regions 1A to 4A via the gate insulating film GI3 or the insulating film IF1. The silicon film AM1 is formed by a film formation process using, for example, the CVD method, and is formed within a temperature range of 400 degrees Celsius or more and 550 degrees Celsius or less. A thickness of the silicon film AM1 is, for example, 15 nm or more and 30 nm or less.

Note that when the thickness of the silicon film AM1 is relatively small, such as 30 nm or less, the silicon film AM1 is formed in an amorphous state without being crystallized, even if the temperature of the film formation process is, for example, 600 degrees Celsius or more.

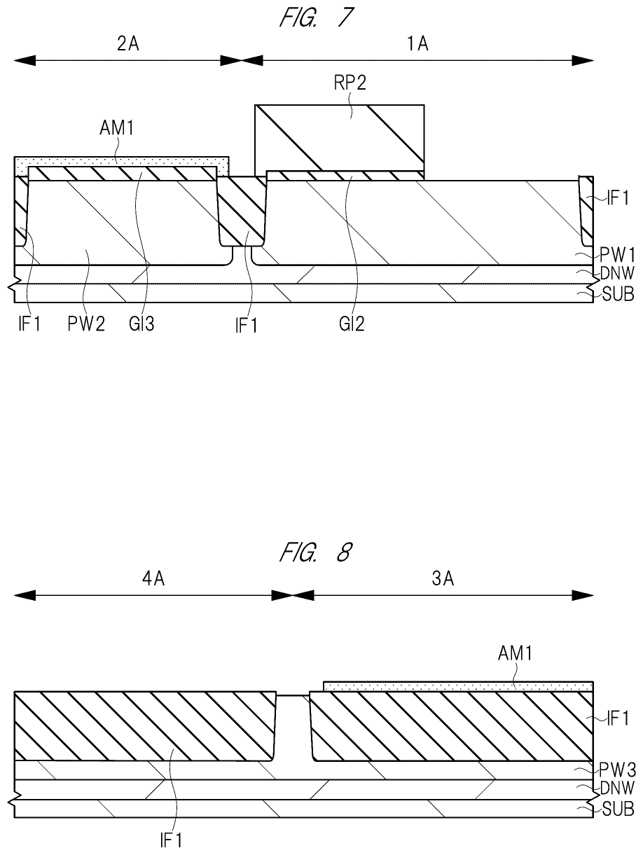

As illustrated in FIG. 5 and FIG. 6, the silicon film AM1 located in the region 1A and the region 4A is removed such that the silicon film AM1 located in the region 2A and the region 3A is left.

First, a resist pattern RP1 is formed on the silicon film AM1. The resist pattern RP1 has a pattern that selectively covers the silicon film AM1 located in the region 2A and the region 3A. Next, an anisotropic etching is performed using the resist pattern RP1 as a mask to remove the silicon film AM1 exposed from the resist pattern RP1. Next, an isotropic etching is performed using the resist pattern RP1 as a mask to remove the gate insulating film GI3 exposed from the resist pattern RP1. Thereafter, the resist pattern RP1 is removed by an ashing process.

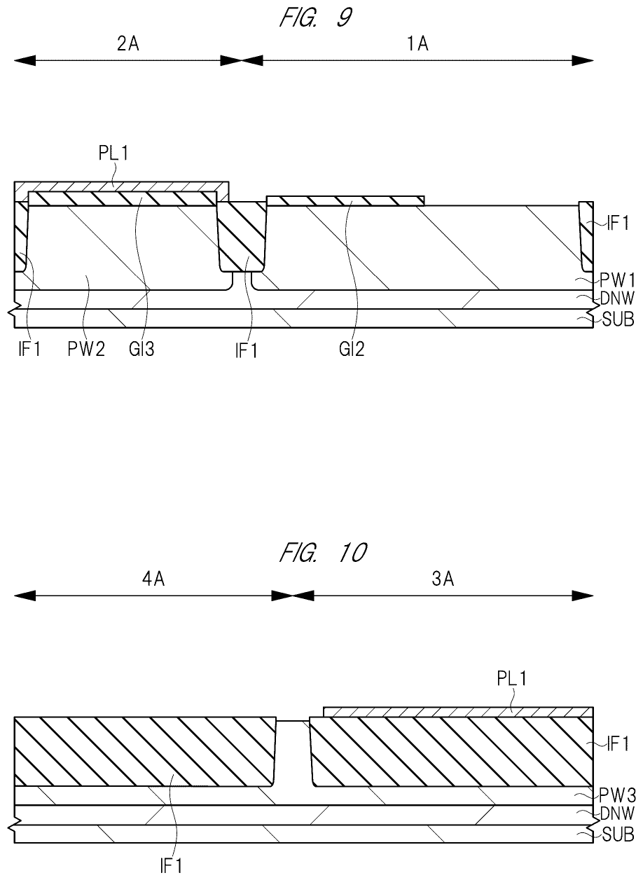

As illustrated in FIG. 7 and FIG. 8, first, a gate insulating film G12 is formed on the semiconductor substrate SUB located in the region 1A, on the silicon film AM1 located in the region 2A, and on the silicon film AM1 located in the region 3A by, for example, thermal oxidation. The gate insulating film GI2 is, for example, a silicon oxide film, and has a thickness of, for example, 5 nm or more and 7 nm or less. Next, a resist pattern RP2 is formed on a part of the gate insulating film GI2 located in the region 1A. Next, an isotropic etching is performed using the resist pattern RP2 as a mask to remove the gate insulating film GI2 exposed from the resist pattern RP2. Thereafter, the resist pattern RP2 is removed by an ashing process.

The portion of the region 1A where the gate insulating film G12 is left is used for the selection transistor 10. The portion of the region 1A where the gate insulating film GI2 is removed and the semiconductor substrate SUB is exposed is used for the memory transistor MQ. In the region 2A and the region 3A, the silicon film AM1 is exposed, but the thickness of the silicon film AM1 is reduced because of the presence of the gate insulating film GI2.

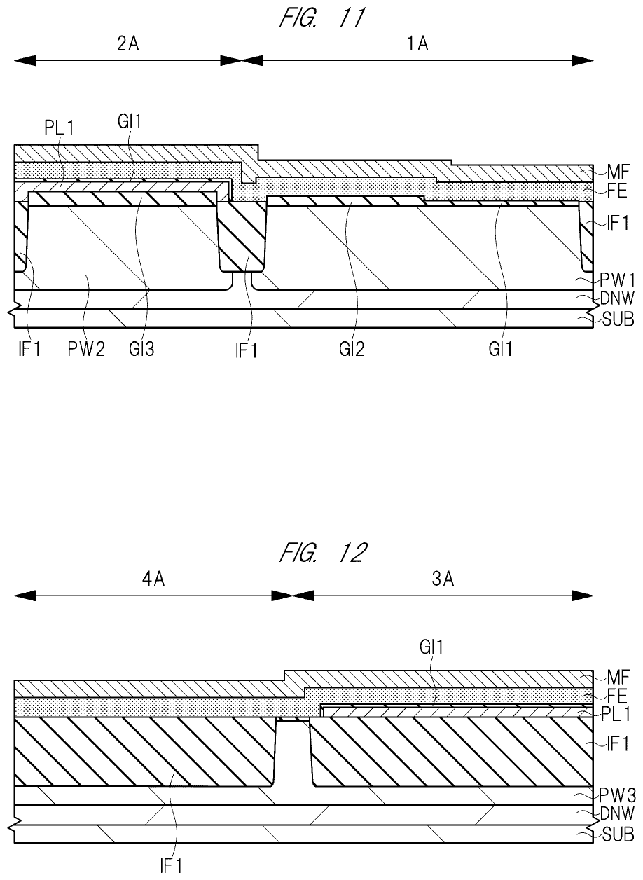

As illustrated in FIG. 9 and FIG. 10, the silicon film AM1 is crystallized by a heat treatment to form the polycrystalline silicon film PL1. This heat treatment is performed in a nitrogen atmosphere, within a temperature range of 800 degrees Celsius or more and 1000 degrees Celsius or less, and for a time range of 10 seconds or more and 100 seconds or less. In this state, a thickness of the polycrystalline silicon film PL1 is preferably 20 nm or less.

As illustrated in FIG. 11 and FIG. first, a gate insulating film GI1 is formed on the semiconductor substrate SUB located in the region 1A, on the polycrystalline silicon film PL1 located in the region 2A, and on the polycrystalline silicon film PL1 located in the region 3A by thermal oxidation using the ISSG (In Situ Steam Generation) oxidation method. The gate insulating film GI1 is, for example, a silicon oxide film, and has a thickness of, for example, 1 nm or more and 5 nm or less.

Next, by a film formation process using, for example, the ALD (Atomic Layer Deposition) method, the ferroelectric film FE is formed on the semiconductor substrate SUB located in the region 1A via the gate insulating film GIL or the gate insulating film GI2, the ferroelectric film FE is formed on the polycrystalline silicon film PL1 located in the region 2A and the region 3A via the gate insulating film GI1, and the ferroelectric film FE is formed on the semiconductor substrate SUB located in the region 4A via the insulating film IF1. In this state, the ferroelectric film FE is in an amorphous state.

The ferroelectric film FE is an HfO₂ film or an HfO₂ film to which at least one of zirconium (Zr), silicon (Si), nitrogen (N), carbon (C), and aluminum (Al) is added. A thickness of the ferroelectric film FE is, for example, 4 nm or more and 20 nm or less.

Next, a metal film MF is formed on the ferroelectric film FE located in the regions 1A to 4A by a film formation process using, for example, the CVD method or the sputtering method. The metal film MF is, for example, a titanium nitride film. A thickness of the metal film MF is, for example, 10 nm or more and 20 nm or less.

Next, the ferroelectric film FE is crystallized by a heat treatment to form the orthorhombic ferroelectric film FE. This heat treatment is performed within a temperature range of 400 degrees Celsius or more and 600 degrees Celsius or less. Here, the metal film MF applies stress to the ferroelectric film FE during the heat treatment, and controls the crystal orientation of the ferroelectric film FE. In other words, the metal film MF has a function of orienting the crystal phase of the ferroelectric film FE to an orthorhombic crystal.

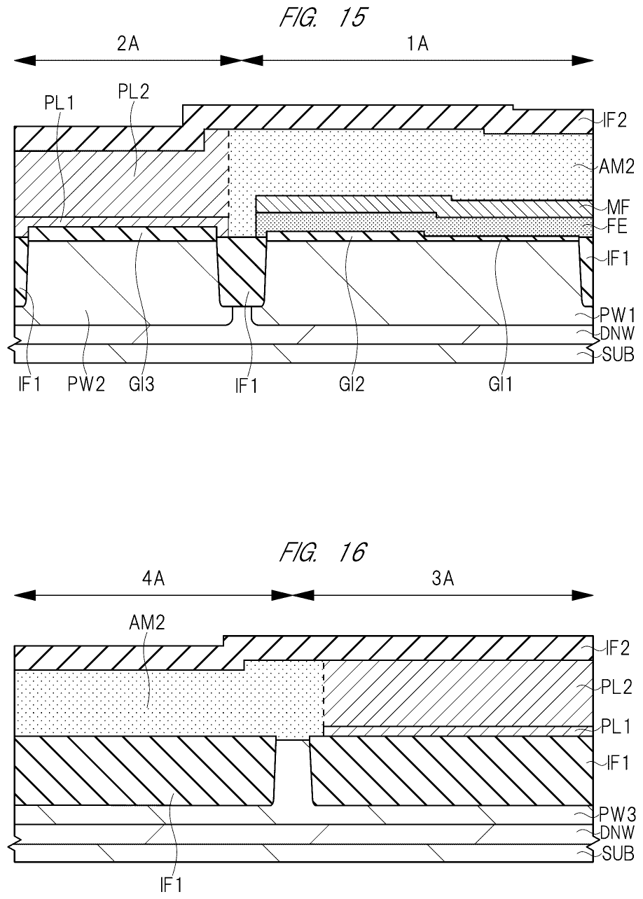

As illustrated in FIG. 13 and FIG. 14, the metal film MF and the ferroelectric film FE located in the regions 2A to 4A are removed such that the metal film MF and the ferroelectric film FE located in the region 1A are left.

First, a resist pattern RP3 is formed on the metal film MF. The resist pattern RP3 has a pattern that selectively covers the metal film MF located in the region 1A. Next, an anisotropic etching is performed using the resist pattern RP3 as a mask to remove the metal film MF and the ferroelectric film FE exposed from the resist pattern RP3. Thereafter, the resist pattern RP3 is removed by an ashing process.

In the above anisotropic etching, over-etching is performed such that the metal film MF and the ferroelectric film FE located in the regions 2A to 4A are surely removed. This over-etching also removes the gate insulating film GI1 formed on the polycrystalline silicon film PL1 in the region 2A and the region 3A. Furthermore, the thickness of the polycrystalline silicon film PL1 is reduced because of the presence of the gate insulating film GI1.

The polycrystalline film silicon PL1 functions as a protective film for protecting the gate insulating film GI2 located in the region 2A from the above over-etching.

Here, the reason why the thickness of the polycrystalline silicon film PL1 is preferably 20 nm or less in the state of FIG. 9 and FIG. 10 will be described. The metal film MF and the ferroelectric film FE are formed not only on the upper surface of the polycrystalline silicon film PL1 but also on the side surfaces of the polycrystalline silicon film PL1. Therefore, as the thickness of the polycrystalline silicon film PL1 becomes larger, the step difference becomes larger, and the height of the metal film MF and the ferroelectric film FE formed on the side surfaces of the polycrystalline silicon film PL1 becomes larger.

As a result, even after removing the metal film MF and the ferroelectric film FE formed on the upper surface of the polycrystalline silicon film PL1, it becomes difficult to completely remove the metal film MF and the ferroelectric film FE formed on the side surfaces of the polycrystalline silicon film PL1. Therefore, in order to reduce such a step difference and make it easier to completely remove the metal film MF and the ferroelectric film FE, the thickness of the polycrystalline silicon film PL1 is preferably as small as possible, and is preferably 20 nm or less.

In addition, considering the purpose of making the polycrystalline silicon film PL1 function as a protective film for the gate insulating film GI2, it is not always necessary to form the polycrystalline silicon film PL1 in the region 3A. Furthermore, after removing the metal film MF and the ferroelectric film FE, the polycrystalline silicon film PL1 located in the region 2A and the region 3A may be removed.

In the first embodiment, the polycrystalline silicon film PL1 is intentionally formed in the region 3A, and the polycrystalline silicon film PL1 is left in the region 2A and the region 3A. The reason for this will be described in detail later.

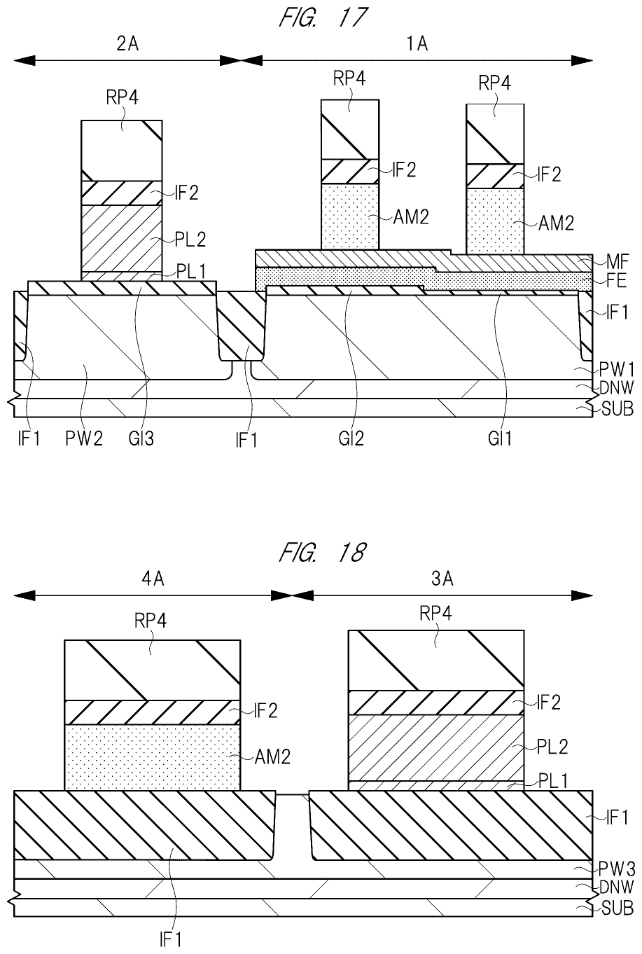

As illustrated in FIG. 15 and FIG. 16, first, a silicon film is formed on the metal film MF located in the region 1A, the silicon film is formed on the polycrystalline silicon film PL1 located in the region 2A, the silicon film is formed on the polycrystalline silicon film PL1 located in the region 3A, and the silicon film is formed on the semiconductor substrate SUB located in the region 4A via the insulating film IF1.

The silicon film is formed by a film formation process using, for example, the CVD method, and is formed within a temperature range of 400 degrees Celsius or more and 550 degrees Celsius or less. A thickness of the silicon film is larger than the thickness of the polycrystalline silicon film PL1, for example, 40 nm or more and 100 nm or less.

In the film formation process, a silicon film in amorphous state is usually formed. Therefore, in the region 1A and the region 4A, the silicon film is formed as a silicon film in amorphous state AM2. On the other hand, in the region 2A and the region 3A, since the polycrystalline silicon film PL1 functions as a seed film, the silicon film is formed as the polycrystalline silicon film PL2.

If the thickness of the polycrystalline silicon film PL1 is too small, the polycrystalline silicon film PL1 may not function as a seed film. In order to make the polycrystalline silicon film PL1 function as a seed film, it is preferable that the thickness of the polycrystalline silicon film PL1 is 5 nm or more. Also, considering the purpose of making it easier to completely remove the metal film MF and the ferroelectric film FE formed on the side surfaces of the polycrystalline silicon film PL1 as described above, it is preferable that the thickness of the polycrystalline silicon film PL1 is 5 nm or more and 20 nm or less.

Next, by photolithography and ion implantation, n-type impurities such as arsenic or phosphorus are introduced into the silicon film AM2 located in the region 1A, the polycrystalline silicon film PL2 and the polycrystalline silicon film PL1 located in the region 2A, the polycrystalline silicon film PL2 and the polycrystalline silicon film PL1 located in the region 3A, and the silicon film AM2 located in the region 4A.

Furthermore, although not illustrated, by photolithography and ion implantation, p-type impurities such as boron or boron difluoride are introduced into the polycrystalline silicon film to be a gate electrode of the p-type MISFET in the region 2A, the polycrystalline silicon film to be a p-type resistance element in the region 3A, and the silicon film in amorphous state to be a p-type resistance element in the region 4A.

Thereafter, an insulating film IF2 is formed on the silicon film AM2 and the polycrystalline silicon film PL2 by a film formation process using, for example, the CVD method. The insulating film IF2 is, for example, a silicon nitride film and has a thickness of, for example, 20 nm or more and 40 nm or less.

In the manufacturing process illustrated in FIG. 17 to FIG. 20, the silicon film AM2, the metal film MF, and the ferroelectric film FE located in the region 1A are patterned, the polycrystalline silicon film PL2 and the polycrystalline silicon film PL1 located in the region 2A are patterned, the polycrystalline silicon film PL2 and the polycrystalline silicon film PL1 located in the region 3A are patterned, and the silicon film AM2 located in the region 4A is patterned.

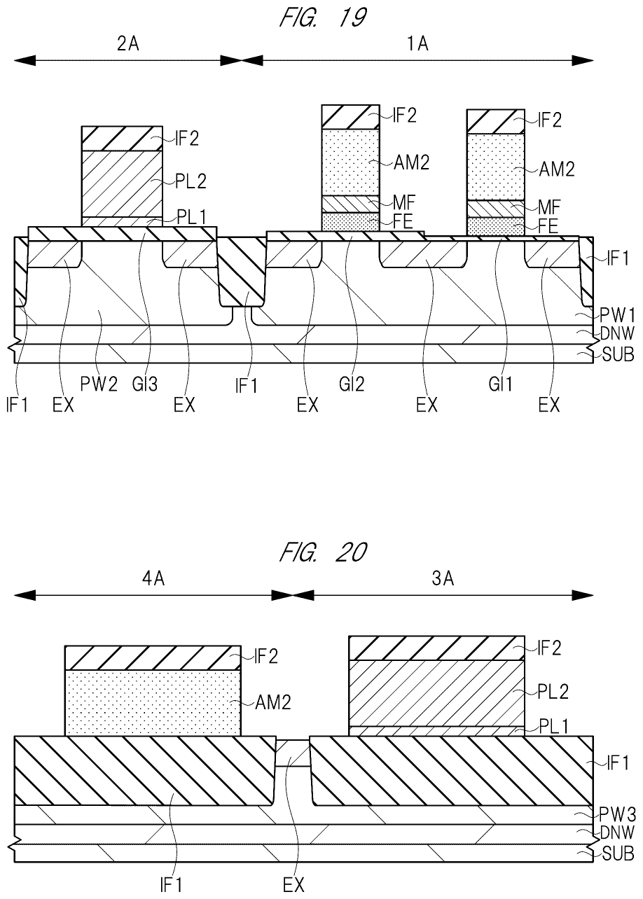

As illustrated in FIG. 17 and FIG. 18, first, a resist pattern RP4 is formed on the insulating film IF2. The resist pattern RP4 has a pattern that selectively covers a part of the insulating film IF2 located in the regions 1A to 4A. Next, an anisotropic etching is performed using the resist pattern RP4 as a mask to remove the insulating film IF2, the silicon film AM2, the polycrystalline silicon film PL2, and the polycrystalline silicon film PL1 exposed from the resist pattern RP4. Thereafter, the resist pattern RP4 is removed by an ashing process.

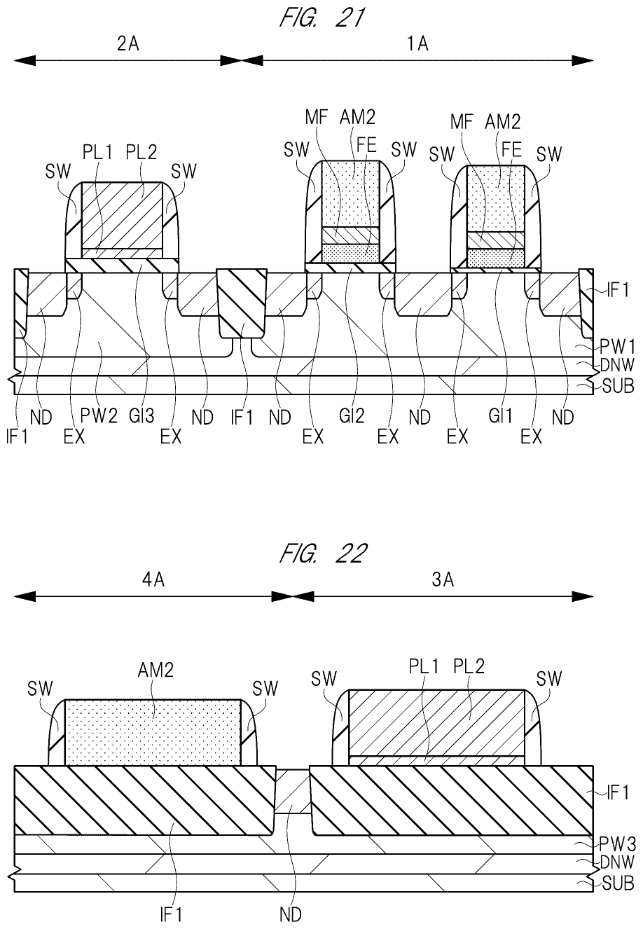

As illustrated in FIG. 19 and FIG. 20, first, an anisotropic etching is performed using the insulating film IF2 as a mask to remove the metal film MF and the ferroelectric film FE exposed from the insulating film IF2 in the region 1A.

Next, by photolithography and ion implantation, n-type impurities such as arsenic or phosphorus are introduced into the semiconductor substrate SUB located in the regions 1A to 4A, thereby forming n-type extension regions (impurity regions) EX.

Furthermore, although not illustrated, by photolithography and ion implantation, p-type impurities such as boron or boron difluoride are introduced into the semiconductor substrate SUB located in the region 2A, thereby forming p-type extension regions to be a source region or drain region of the p-type MISFET.

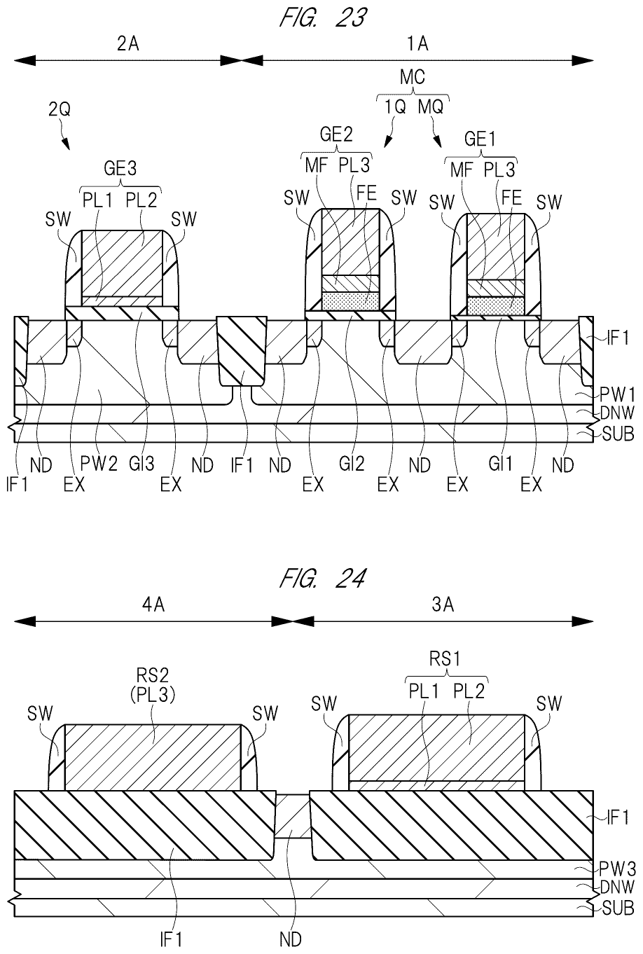

As illustrated in FIG. 21 and FIG. 22, first, in the regions 1A to 4A, a silicon oxide film and a silicon nitride film are sequentially formed on the semiconductor substrate SUB so as to cover the insulating film IF2 by a film formation process using, for example, the CVD method. Next, the silicon oxide film and the silicon nitride film are processed by an anisotropic etching, thereby forming sidewall spacers SW. Note that the insulating film IF2 is removed by this anisotropic etching.

In the region 1A, the sidewall spacer SW is formed on each of the side surfaces of the ferroelectric film FE, the metal film MF, and the silicon film AM2. In the region 2A and the region 3A, the sidewall spacer SW is formed on each of the side surfaces of the polycrystalline silicon film PL2 and the polycrystalline silicon film PL1. In the region 4A, the sidewall spacer SW is formed on the side surfaces of the silicon film AM2.

Next, by photolithography and ion implantation, n-type impurities such as arsenic or phosphorus are introduced into the semiconductor substrate SUB located in the regions 1A to 4A, thereby forming n-type diffusion regions (impurity regions) ND. The diffusion regions ND and the extension regions EX form a part of the source region or a part of the drain region of the memory transistor MQ and the selection transistor 10 in the region 1A, and form a part of the source region or a part of the drain region of the MISFET 20 in the region 2A.

When forming the diffusion regions ND, the n-type impurities are introduced also into the silicon film AM2 located in the region 1A, the polycrystalline silicon film PL2 and the polycrystalline silicon film PL1 located in the region 2A, the polycrystalline silicon film PL2 and the polycrystalline silicon film PL1 located in the region 3A, and the silicon film AM2 located in the region 4A.

Furthermore, although not illustrated, by photolithography and ion implantation, p-type impurities such as boron or boron difluoride are introduced into the semiconductor substrate SUB located in the region 2A, thereby forming p-type diffusion regions to be the source region or the drain region of the p-type MISFET.

When forming the p-type diffusion regions, the p-type impurities are introduced also into the polycrystalline silicon film to be the gate electrode of the p-type MISFET in the region 2A, the polycrystalline silicon film to be the p-type resistance element in the region 3A, and the silicon film in amorphous state to be the p-type resistance element in the region 4A.

As illustrated in FIG. 23 and FIG. 24, by heat treatment, the diffusion regions ND and the extension regions EX are activated, and the silicon films AM2 located in the region 1A and the region 4A are crystallized, thereby forming the polycrystalline silicon films PL3. This heat treatment is performed by the RTA (Rapid Thermal Annealing) method in a nitrogen atmosphere, within a temperature range of 1000 degrees Celsius or more and 1100 degrees Celsius or less, and for a time range of 0.1 seconds or more and 1.0 seconds or less.

The polycrystalline silicon film PL3 and the metal film MF located in the region 1A function as a gate electrode GE1 of the memory transistor MQ and a gate electrode GE2 of the selection transistor 10. The polycrystalline silicon film PL2 and the polycrystalline silicon film PL1 located in the region 2A function as a gate electrode GE3 of the MISFET 2Q. The polycrystalline silicon film PL2 and the polycrystalline silicon film PL1 located in the region 3A function as the resistance element RS1. The polycrystalline silicon film PL3 located in the region 4A functions as the resistance element RS2.

As described above, the ferroelectric memory cell MC including the memory transistor MQ and the selection transistor 10 is formed in the region 1A, the MISFET 20 is formed in the region 2A, the resistance element RS1 is formed in the region 3A, and the resistance element RS2 is formed in the region 4A.

### Main Features of First Embodiment

As illustrated in FIG. 15 and FIG. 16, when a silicon film for the gate electrode of the ferroelectric memory cell MC is formed on the metal film MF in the region 1A, the temperature of the film formation process is set to 400 degrees Celsius or more and 550 degrees Celsius or less. Therefore, the silicon film in amorphous state AM2 is formed on the metal film MF. As a result, it is possible to solve the problem that the abnormal growth of the polycrystalline silicon film is likely to occur when forming the polycrystalline silicon film on the metal film MF.

On the other hand, in the region 3A, the silicon film formed by the same manufacturing step as the silicon film of the ferroelectric memory cell MC is applied to the resistance element RS1. Therefore, since it is not necessary to separately form the silicon film for the resistance element RS1, the manufacturing process can be simplified and the increase in the manufacturing cost can be suppressed. When the silicon film in amorphous state AM2 is applied to the resistance element RS1, the silicon film AM2 is crystallized by the heat treatment illustrated in FIG. 23 and FIG. 24. However, in that case, it has been found that the sheet resistance of the resistance element RS1 becomes lower than the sheet resistance of the case of forming the resistance element from a polycrystalline silicon film in advance.

Therefore, in the first embodiment, as described with reference to FIG. 9 and FIG. 10, the polycrystalline silicon film PL1 is formed by crystalizing the silicon film AM1 formed in the region 2A and the region 3A. Further, the polycrystalline silicon film PL1 is left in the region 2A and the region 3A without removing it. Since the polycrystalline silicon film PL1 functions as a seed film in the region 2A and the region 3A when forming the silicon film in amorphous state AM2, the silicon film in the region 2A and the region 3A is formed as the polycrystalline silicon film PL2.

FIG. 25 illustrates a comparison between the resistance element RS1 (polycrystalline silicon film PL1/polycrystalline silicon film PL2) of the first embodiment and a resistance element of a comparative example. The resistance element of the comparative example is made of a polycrystalline silicon film obtained by crystallizing a silicon film in amorphous state.

In the case of the resistance element of the comparative example, ions are implanted into the silicon film when the silicon film is in an amorphous state in the manufacturing step illustrated in FIG. 15 and FIG. 16 and in the manufacturing step illustrated in FIG. 21 and FIG. 22. One possible reason for the low sheet resistance is that ion implantation into the silicon film in amorphous state has increased the solid solubility. Also, the thickness of the silicon film in amorphous state is, for example, 40 nm or more and 100 nm or less. Another possible reason for the low sheet resistance is that the grain size becomes large in the polycrystalline silicon film crystallized from an amorphous state.

In the first embodiment, since the polycrystalline silicon film PL1 functions as a seed film, when a silicon film is formed on the seed film, a large number of crystal nuclei are present in the silicon film. Therefore, it is contemplated that the grain size in the polycrystalline silicon film PL3 of the first embodiment is smaller than that in the polycrystalline silicon film of the comparative example.

Note that a polycrystalline silicon film formed at a film formation temperature of about 600 degrees Celsius has been conventionally used as a resistance element, but the sheet resistance of the resistance element RS1 of the first embodiment is almost the same as that of the conventional resistance element. In this way, in the first embodiment, the reduction in the sheet resistance of the resistance element RS1 can be suppressed, and the fluctuation in the characteristics of the resistance element RS1 can be suppressed, so that the reliability of the semiconductor device can be improved.

Furthermore, in the first embodiment, the resistance element RS2 is formed in the region 4A. Since the polycrystalline silicon film PL1 is removed in the region 4A, the resistance element RS2 is made of the polycrystalline silicon film PL3 obtained by crystallizing the silicon film in amorphous state AM2. In other words, the resistance element RS2 corresponds to the resistance element of the comparative example, and has a sheet resistance lower than that of the resistance element RS1.

Depending on the product specifications, a plurality of resistance elements having different sheet resistances may be required. As described in the first embodiment, by simply leaving the polycrystalline silicon film PL1 in the region 3A and removing the polycrystalline silicon film PL1 in the region 4A, the resistance element RS1 and the resistance element RS2 having different sheet resistances can be obtained without adding any manufacturing steps. In the case of the first embodiment, the n-type resistance element RS1, the p-type resistance element RS1, the n-type resistance element RS2, and the p-type resistance element RS2 having different sheet resistances can be obtained.

Although the invention made by the inventors of this application has been specifically described above based on the embodiment, the present invention is not limited to the above embodiment and may be modified in various ways within the range not departing from the gist of the present invention.

What is claimed is:

1. A method of manufacturing a semiconductor device including a first region in which a ferroelectric memory cell is formed and a second region located at a periphery of the first region, the method comprising:
(a) preparing a semiconductor substrate;
(b) forming a first silicon film in amorphous state on the semiconductor substrate located in the first region and the second region;
(c) after the (b), removing the first silicon film located in the first region such that the first silicon film located in the second region is left;
(d) after the (c), forming a first polycrystalline silicon film by crystallizing the first silicon film by a first heat treatment;
(e) after the (d), forming a ferroelectric film on the semiconductor substrate located in the first region and on the first polycrystalline silicon film located in the second region;
(f) after the (e), forming a metal film on the ferroelectric film located in the first region and the second region;
(g) after the (f), removing the metal film and the ferroelectric film located in the second region such that the metal film and the ferroelectric film located in the first region are left; and
(h) after the (g), forming a second silicon film on the metal film located in the first region and on the first polycrystalline silicon film located in the second region.

2. The method of manufacturing the semiconductor device according to claim 1,
wherein in the (h), the second silicon film formed on the metal film is formed in an amorphous state, and the second silicon film formed on the first polycrystalline silicon film is formed as a second polycrystalline silicon film because the first polycrystalline silicon film functions as a seed film.

3. The method of manufacturing the semiconductor device according to claim 2, further comprising:
(i) after the (h), patterning the second silicon film, the metal film, and the ferroelectric film located in the first region, and patterning the first polycrystalline silicon film and the second polycrystalline silicon film located in the second region;
(j) after the (i), forming an impurity region in the semiconductor substrate located in the first region; and
(k) after the (j), activating the impurity region and forming a third polycrystalline silicon film by crystallizing the second silicon film located in the first region by a second heat treatment.

4. The method of manufacturing the semiconductor device according to claim 3,
wherein after the (k), the third polycrystalline silicon film and the metal film located in the first region function as a gate electrode of a transistor included in the ferroelectric memory cell, and the first polycrystalline silicon film and the second polycrystalline silicon film located in the second region function as a gate electrode of a resistance element or a MISFET.

5. The method of manufacturing the semiconductor device according to claim 4,
wherein the semiconductor device further includes a third region located at the periphery of the first region and different from the second region,
wherein in the (b), the first silicon film is formed also in the third region,
wherein in the (c), the first silicon film located in the first region and the third region is removed such that the first silicon film located in the second region is left,
wherein in the (e), the ferroelectric film is formed also in the third region,
wherein in the (f), the metal film is formed also on the ferroelectric film located in the third region,
wherein in the (g), the metal film and the ferroelectric film located in the second region and the third region are removed such that the metal film and the ferroelectric film located in the first region are left,
wherein in the (h), the second silicon film in amorphous state is formed also on the semiconductor substrate located in the third region,
wherein in the (i), the second silicon film located in the third region is also patterned,
wherein in the (k), a fourth polycrystalline silicon film is formed by crystallizing the second silicon film located in the third region by the second heat treatment, and
wherein after the (k), the first polycrystalline silicon film and the second polycrystalline silicon film located in the second region function as a first resistance element, and the fourth polycrystalline silicon film located in the third region functions as a second resistance element.

6. The method of manufacturing the semiconductor device according to claim 5,
wherein a sheet resistance of the second resistance element is lower than a sheet resistance of the first resistance element.

7. The method of manufacturing the semiconductor device according to claim 2,
wherein in the (h), a thickness of the first polycrystalline silicon film is 5 nm or more.

8. The method of manufacturing the semiconductor device according to claim 7,
wherein in the thickness of the first polycrystalline silicon film is 20 nm or less.

9. The method of manufacturing the semiconductor device according to claim 1,
wherein a thickness of the second silicon film is larger than a thickness of the first polycrystalline silicon film.

10. The method of manufacturing the semiconductor device according to claim 9,
wherein the thickness of the first polycrystalline silicon film is 5 nm or more and 20 nm or less, and
wherein the thickness of the second silicon film is 40 nm or more and 100 nm or less.

11. The method of manufacturing the semiconductor device according to claim 1,
wherein in the (d), the first heat treatment is performed in a nitrogen atmosphere, within a temperature range of 800 degrees Celsius or more and 1000 degrees Celsius or less, and for a time range of 10 seconds or more and 100 seconds or less.

12. The method of manufacturing the semiconductor device according to claim 1,
wherein in the (h), the second silicon film is formed within a temperature range of 400 degrees Celsius or more and 550 degrees Celsius or less.

13. The method of manufacturing the semiconductor device according to claim 1,
wherein the metal film is a titanium nitride film.
